(19) United States
(12) Patent Application Publication
(10) Pub. No.: US 2026/0353826 A1
(43) Pub. Date: Nov. 5, 2026

(54) MULTIPLE CONVERSION GAIN DESIGN FOR CMOS IMAGE SENSOR

(71) Applicant: Taiwan Semiconductor Manufacturing Company, Ltd., Hsinchu (TW)

(72) Inventors: Chih-Kuan Yu, Nantou County (TW); Feng-Chi Hung, Chu-Bei City (TW); Wen-I Hsu, Tainan City (TW); Shang-Fu Yeh, Hsin Chu City (TW); Jen-Cheng Liu, Hsin-Chu City (TW); Dun-Nian Yaung, Taipei City (TW)

(21) Appl. No.: 19/742,111

(22) Filed: Jul. 15, 2026

Related U.S. Application Data
(63) Continuation of application No. 18/929,748, filed on Oct. 29, 2024.
(60) Provisional application No. 63/663,721, filed on Jun. 25, 2024.

(51) Int. Cl. H10F 39/00; H10F 39/18; H10W 80/00; H10W 90/00

(52) U.S. Cl. CPC H10F 39/8023; H10F 39/018; H10F 39/182; H10F 39/8053; H10F 39/809; H10F 39/811; H10W 80/312; H10W 80/327; H10W 90/792

(57) ABSTRACT

An image sensor having a quad pixel structure has a quad pixel circuit including four photodetector pixel circuits and a bridge circuit. The bridge circuit selectively couples the floating diffusion nodes corresponding to the four photodetector pixels and allows the four photodetector pixel circuits to operate selectively in either a quad pixel mode, a dual pixel mode, or a single pixel mode. Each of the photodetector pixel circuits may include a multiple conversion gain circuit to provide a wide dynamic range.

### REFERENCE TO RELATED APPLICATIONS

This Application is a Continuation of U.S. Application number 18/929,748, filed on Oct. 29, 2024, which claims the benefit of U.S. Provisional Application number 63/663,721, filed on Jun. 25, 2024. The contents of the above-referenced Patent Applications are hereby incorporated by reference in their entirety.

### BACKGROUND

Many modern day electronic devices (e.g., digital cameras, optical imaging devices, etc.) comprise image sensors. An image sensor includes an array of photosensitive structures which transduce light into electrical charge. Examples of image sensors include charge-coupled device (CCD) image sensors and complementary metal-oxide-semiconductor (CMOS) image sensors. Compared to CCD image sensors, CMOS image sensors are favored due to low power consumption, small size, fast data processing, a direct output of data, and low manufacturing cost.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1-4 provide circuit diagrams illustrating quad pixel circuits for image sensor according to various embodiments of the present disclosure.

FIG. 5 is a chart illustrating the operation of a triple conversion gain circuit according to some embodiments.

FIG. 6A-6B provide circuit diagrams for multiple conversion gain circuits according to various embodiments.

FIG. 7 illustrates a cross-sectional view of an image sensor in accordance with some embodiments.

FIG. 8 illustrates the mapping of data to form images from an image sensor according to some embodiments.

FIG. 9-14 provide circuit diagrams illustrating the distributions of image sensor component among device layers in accordance with various embodiments.

FIG. 15 illustrates a plan view of a quad pixel group in accordance with an embodiment.

FIGS. 16-22 provide a series of cross-sectional views illustrating an embodiment of a manufacturing process according to the present disclosure.

FIG. 23 provides a flow chart for a manufacturing process in accordance with some embodiments of the present disclosure.

FIG. 24 provides a flow chart illustrating an embodiment of a method of operating a quad pixel group.

FIG. 25 provides a flow chart illustrating a reset operation for an image sensor in accordance with some embodiments.

FIG. 26-27 provide flow charts illustrating image sensor read operations in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature’s relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

One type of CMOS image sensor has an array of photodetectors each of which includes a photosensitive area within a semiconductor substrate, a transfer gate, a floating diffusion node, a source follower, a row select transistor, and a reset transistor. When the reset transistor is closed, the floating diffusion node is brought to a reference voltage. The photosensitive area is part of a photodiode or other photodetector structure that transduces light into electrical charge. Light exposure causes electrical charge to accumulate in the photodiode or other photodetector structure until the transfer gate is closed whereupon the electrical charge flows to the floating diffusion node. The electrical charge alters the floating diffusion node voltage. The floating diffusion node voltage is applied to the source follower gate electrode. When the corresponding row select transistor is closed, current flows through the source follower at a rate that depends on the floating diffusion node voltage. The current is detected and used to infer the amount of electrical charge that was transferred to the floating diffusion node, which in turn reflects the amount of radiation that was incident on the photosensitive area over the sampling interval.

Conversion gain is a significant parameter for a CMOS image sensor of the type just described. The conversion gain is related to the capacitance of the floating diffusion node. If conversion gain is too high, a photodetector pixel circuit may become saturated and unable to differentiate among light intensity levels. If conversion gain is too low, there will be excessive noise in comparison to the signal and variations in light intensity at lower light intensity levels will be lost. Low conversion gain is generally desirable for high levels of illumination. High conversion is generally desirable for low levels of illumination. The range between the lowest and highest illumination levels at which a CMOS image sensor is effective is its dynamic range. The dynamic range depends on the floating diffusion node capacitance.

Dynamic range may be increased by adding a dual conversion gain circuit to the photodetector pixel circuit. A dual conversion gain circuit allows higher light intensity levels to be accommodated by selectively adding capacitance to the floating diffusion node. The source of capacitance may be a lateral overflow integration capacitor (LOFIC). In a high conversion gain mode, the dual conversion gain circuit adds the extra capacitance to the floating diffusion node and decreases conversion gain. In a low conversion gain mode, the dual conversion gain circuit isolates the extra capacitance from the floating diffusion node. Dual conversion gain primarily accommodates higher light intensity levels. The concept of dual conversion gain may be generalized to include other multiple conversion gain circuits, such as a triple conversion gain circuit which allows selection among three possible capacitance levels.

One approach to extending the dynamic range to accommodate lower light intensity levels is to use a quad pixel structure. In the quad pixel structure two-by-two sub-arrays of adjacent photodetector pixels are disposed under each color filter in a color filter/microlens array. When light intensity levels are high, the four photodetector pixels are operated independently to provide high resolution images. When light intensity levels are lower, the four photodetector pixels are combined into one pixel to provide one quarter resolution images having relatively lower noise.

One way of enabling combination of data from the four adjacent photodetector pixels is to have them share a single floating diffusion node. Four distinct transfer gates selectively transfer charges from their respective photodiodes to the floating diffusion node. In the high resolution mode, the photodetector pixels are read serially, and the floating diffusion node is reset between each read operation. In the low resolution mode, charges from all four photodiodes are transferred to the floating diffusion node for each read operation. A shortcoming of this approach is that reset times become a limiting factor, particularly when in the high resolution mode where the pixels are read serially and in the low conversion gain mode when an LOFIC is adding extra capacitance to the photodetector pixel circuit.

Another approach to combining data from the four adjacent photodetector pixels is to combine their readings. The photodetector pixels are read by column decoders and the signals from these column decoders are combined during signal processing. A shortcoming of this approach is that each read operation introduces noise. When the outputs of the four read operations are combined, there are four read noise contributions to the resulting data point. The four read noise contributions work counter to the intended benefit of combining the four signals, which is to reduce noise. Another disadvantage to combining signals is that four separate read operations are executed to provide each data point, which extends read times.

In accordance with the present disclosure, the foregoing problems are solved with a bridge circuit that selectively couples the floating diffusion nodes corresponding to the photodetector pixels in a quad pixel circuit. The quad pixel circuit includes four photodetector pixel circuits, each of which may include a multiple conversion gain circuit. The bridge circuit allows these four photodetector pixel circuits to operate selectively in either a quad pixel mode, a dual pixel mode, or a single pixel mode.

In the single pixel mode, the bridge circuit keeps the four floating diffusion nodes of the four photodetector pixel circuits isolated from one another so that each photodetector pixel circuit may operate independently of the others. The multiple conversion gain circuits may be operated to vary the capacitances of the floating diffusion nodes so that each of the photodetector pixels may be in either a high conversion gain mode, a low conversion gain mode, or some intermediate conversion gain mode. In some embodiments, the multiple conversion gain circuits are dual conversion gain circuits. In some embodiments, the multiple conversion gain circuits are triple conversion gain circuits which are operable to add either a first extra capacitance or both a first and a second extra capacitance to floating diffusion mode to selectively provide either a high, a medium, or a low conversion gain mode. The single pixel mode provides high resolution images and is suitable for high levels of light and for lower levels of light when a slow sampling rate is acceptable.

In the dual pixel mode, the bridge circuit links the four floating diffusion nodes of the four photodetector pixel circuits in two pairs so that the four photodetector pixel circuits operate as two photodetector pixel circuits. The transfer gates are operated so that charges accumulated by the photodiodes of paired photodetector pixels mingle in combined floating diffusion nodes. The voltage on a combined floating diffusion node may be read through either or both of the source followers associated with the linked photodetector pixel circuits. In either case, one read operation provides the data from a pair of photodiodes, which results in lower noise as compared to adding the output of two separate read operations. The dual pixel mode provides an intermediate level of resolution. The dual pixel mode may be combined with either high, intermediate, or low conversion gain modes. The multiple conversion gain circuits may all utilize the same conversion gain switching signal(s). In some embodiments, some of the multiple conversion gain circuits have independent mode switching signals so that extra capacitances from either zero, one, or two multiple conversion gain circuits may be selectively added to each of the combined floating diffusion nodes to provide a wide range conversion gain modes.

In the quad pixel mode, the bridge circuit links the four floating diffusion nodes of the four photodetector pixel circuits so that the four photodetector pixel circuits operate as one combined photodetector pixel circuit. The transfer gates are operated so that charges accumulated by the four adjacent photodiodes mingle in the one combined floating diffusion node. The voltage on the combined floating diffusion node may be read through one or more of the four source followers associated with the four photodetector pixel circuits in the quad pixel circuit. One read operation may provide the data from four photodiodes, which results in lower noise as compared to adding the outputs of four separate read operations. The quad pixel mode may be combined with either high, intermediate, or low conversion gain modes. Optionally, the multiple conversion gain circuits have independent mode switching signals so that extra capacitances from either zero, one, two, three, or all of the multiple conversion gain circuits may be selectively added to the combined floating diffusion node to reduce conversion gain in the quad pixel mode. The quad pixel mode provides 1/4 resolution compared to the single pixel mode. The lower resolution image may be more accurate and take less memory than an equivalent full resolution image taken under the same lighting conditions.

The bridge circuit may comprise transistors or other switching structures. In some embodiments the bridge circuit includes three transistors: two transistors for linking the floating diffusion nodes of two adjacent pairs of photodetector pixels and a third transistor for linking the two adjacent pairs. In some embodiments the bridge circuit includes a fourth transistor to maintain equivalence among photodetector pixels and simplify manufacturing. The transistors may be NMOS transistors, PMOS transistors, or other types of transistors.

Another significant performance parameter for a CMOS image sensor is resolution. High resolution is achieved through high pixel density. The area occupied by transistors in the photodetector pixel circuit can limit pixel density. One approach to overcoming that limitation is to use two or three device layers. A first portion of the photodetector pixel circuit including the photodiodes and the transfer gates is located in the first device layer. A second portion of the photodetector pixel circuit is located on the second device layer. An application-specific integrated circuit (ASIC) may be disposed in the peripheral region of the second device layer or in a third device layer.

The photodetector pixel circuit components on the second device layer may include one or more of the row select transistor, the reset transistor, the multiple conversion gain circuit (which may include the reset transistor), and the source follower. In some embodiments, the bridge circuit is on the second device layer. In some other embodiments, the bridge circuit is on the first device layer. Having the bridge circuit on the first device layer may reduce the capacitances of the floating diffusion node and increase conversion gain. In some embodiments, the source followers are on the first device layer together with the bridge circuit while some other components of the quad pixel circuit are on the second device layer. This later structure may provide a high conversion gain mode in which the floating diffusion nodes do not include any contributions to capacitance from wiring that extends from the first device layer to the second device layer.

Unlike the prior art in which a quad pixel structure has one shared floating diffusion node, a quad pixel structure in accordance with the present disclosure allows there to be a separate multiple conversion gain circuit with a separate LOFIC for each photodetector pixel circuit. As pixel density becomes high, it can be difficult to package so many LOFICs. In some embodiments, this problem is solved by placing the LOFICs in the first device layer along with the photodiodes and the transfer gates while other components of the photodetector pixel circuits are disposed in a second device layer. In some embodiments, this problem is solved by placing the LOFICs in the third device layer along with the ASIC.

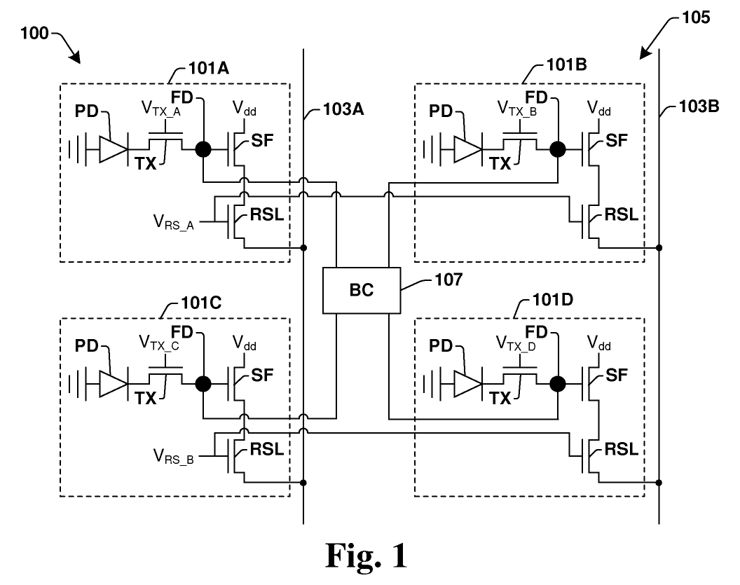

FIG. 1 is a circuit diagram 100 for a portion on an image sensor including a quad pixel circuit 105. The quad pixel circuit 105 comprises four photodetector pixel circuits 101A-101D and a bridge circuit 107. Each of the photodetector pixel circuits 101A-101D comprises a photodiode PD, a floating diffusion node FD, a transfer gate TX, a source follower SF, and a row select transistor RSL. The photodetector pixel circuits 101A-101D circuits may further comprises reset transistors or dual conversion gain circuits (not shown).

The bridge circuit 107 is connected to the four floating diffusion nodes FD and contains circuitry for selectively coupling and uncoupling the four floating diffusion nodes FD to implement various modes. These may include a 1C mode in which the four floating diffusion nodes FD are decoupled, a 2C mode in which the floating diffusion nodes FD of the photodetector pixel circuits 101A and 101C are coupled and the floating diffusion nodes FD of the photodetector pixel circuits 101B and 101D are coupled, and a 4C mode in which all four of the floating diffusion nodes FD are coupled.

The row select transistors RSL of the photodetector pixel circuits 101A and 101C are coupled to a column wire 103A. The row select transistors RSL of the photodetector pixel circuits 101B and 101B are coupled to a column wire 103B. The column wires 103A and 103B are wiring structures that connect to column decoders (not shown). There may be one column decoder for each column in a photodetector array.

The transfer gates TX are selectively actuated by transfer gate signals V_{TX-A}-V_{TX-D}. The transfer gate signals V_{TX-A}-V_{TX-D} may be independent. The source followers SF are selectively actuated by row select signals V_{RS-A} and V_{RS-B}. Each of the row select signals V_{RS-A} and V_{RS-B} is provided by a distinct row driver (not shown). In 1C mode, the row select signals V_{RS-A} and V_{RS-B} are operated serially for each read operation. In 2C and 4C modes, only one of the row select signals V_{RS-A} and V_{RS-B} is used for a read operation.

FIG. 1A is a circuit diagram 110 for a portion on an image sensor including a quad pixel circuit 105A. The quad pixel circuit 105A is like the quad pixel circuit 105 of FIG. 1 except that all four row select transistors RSL are coupled to the column wire 103A. This configuration allows the use of less column wiring and can improve conversion gain by reducing parasitic capacitance, but there is a tradeoff in that the configuration of FIG. 1A entails the use of four separate row select signals V_{RS_A}-V_{RS_D}. The configuration of FIG. 1 has the advantage of allowing an image to be acquired with half as many sequentially executed row driver operations as compared to the configuration of FIG. 1A.

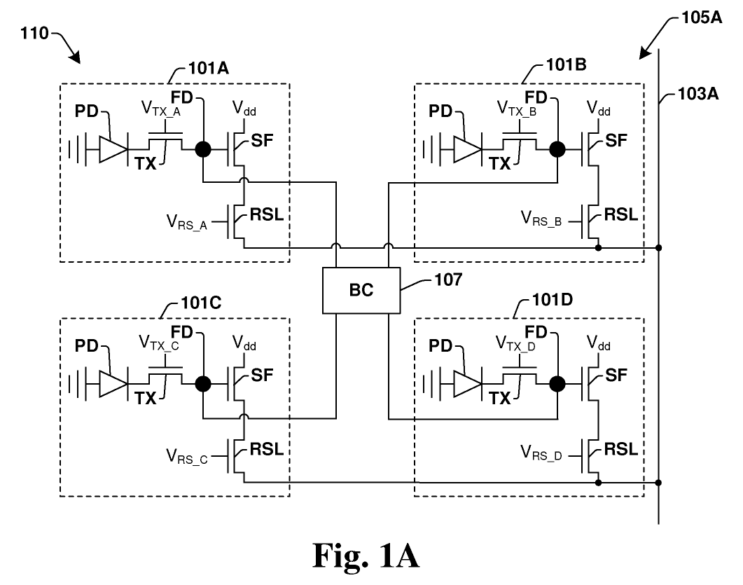

FIG. 2 is a circuit diagram 200 showing the quad pixel circuit 105 for a case in which the bridge circuit 107 is embodied by the bridge circuit 107A. The bridge circuit 107A includes four switch transistors 201A-201D, which may be operated through two control signals V_{SW1} and V_{SW2}. Setting both the control signals V_{SW1} and V_{SW2} low opens all four switch transistors 201A-201D and implements 1C mode. Setting the control signals V_{SW1} low and the control signal V_{SW2} high closes the switch transistors 201B and 201C while keeping the switch transistors 201A and 201D open, which implements 2C mode. Setting both the control signals V_{SW1} and V_{SW2} high closes all four switch transistors 201A-201D and implements 4C mode.

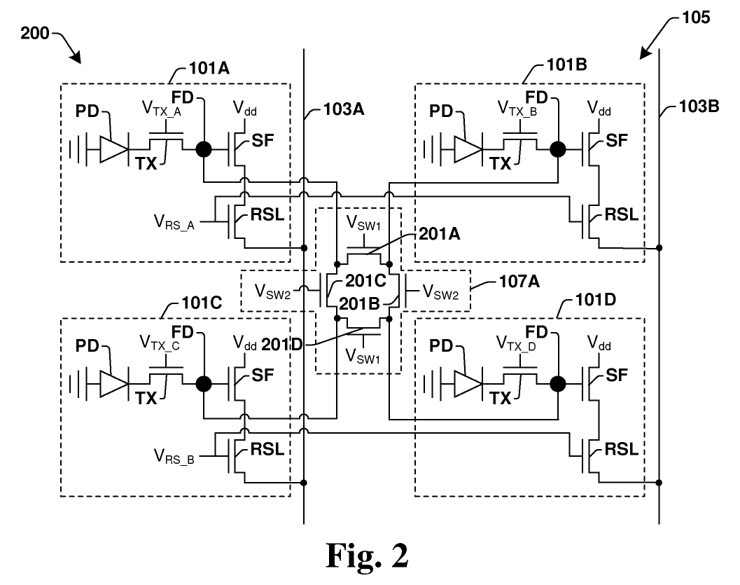

FIG. 3 is a circuit diagram 300 showing the quad pixel circuit 105 for a case in which the bridge circuit 107 is embodied by the bridge circuit 107B. The bridge circuit 107B is like the bridge circuit 107A of FIG. 2 except that it lacks the switch transistor 201D. Eliminating the switch transistor 201D simplifies the circuit and may allow a reduction in the capacitance of the floating diffusion nodes FD. Retaining the switch transistor 201D simplifies manufacturing and simplifies maintaining equal capacitance among the four floating diffusion nodes FD in the quad pixel circuit 105.

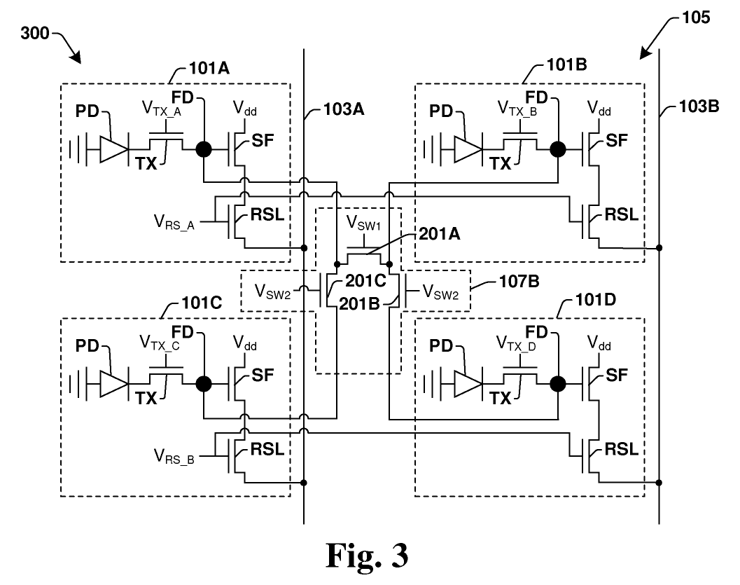

FIG. 4 is a circuit diagram 400 for a quad pixel circuit 405. The quad pixel circuit 405 is like the quad pixel circuit 105 of FIG. 1 except that the quad pixel circuit 405 has the photodetector pixel circuits 401A-401D in place of the photodetector pixel circuits 101A-101D. The photodetector pixel circuits 401A-401D have the components of the photodetector pixel circuits 101A-101D but further include triple conversion gain circuits 409A-409D respectively.

The triple conversion gain circuits 409A-409D may each include a first conversion gain transistor CG1, a second conversion gain transistor CG2, a reset transistor RST, a capacitor control transistor CC, an LOFIC. The reset transistors RST are operated through reset control signals V_{RT_A}-V_{RT_D}. The capacitor control transistors CC may be operated through capacitor control signals V_{CC_A}-V_{CC_D}. The first conversion gain transistors CG1 and the second conversion gain transistors CG2 are operated through the conversion gain control signals V_{CG1_A}-V_{CG1_D} and V_{CG2_A}-V_{CG2_D} to implement either low, medium, or high conversion gain modes.

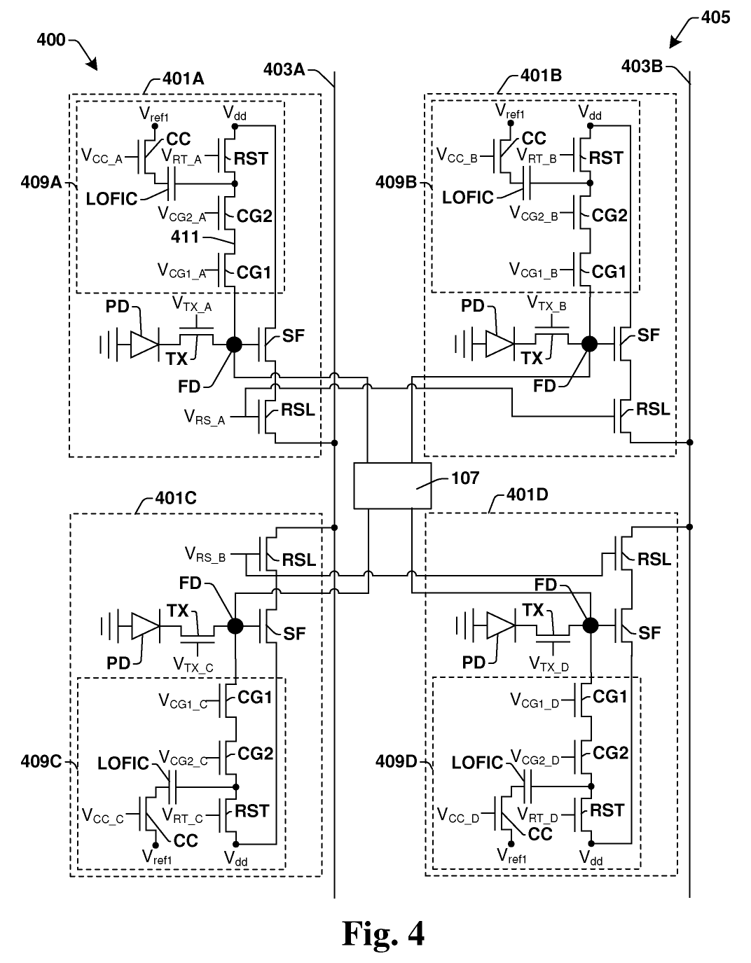

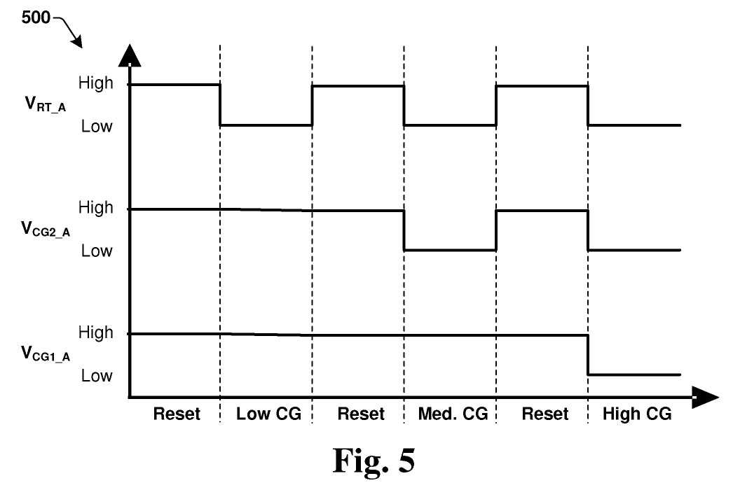

FIG. 5 is a chart 500 illustrating the operation of the triple conversion gain circuit 409A. The triple conversion gain circuits 409B-409D may be operated in similar fashion. For a reset operation, the reset control signal V_{RT_A} and the conversion gain control signals V_{CG1_A} and V_{CG2_A} are all set to high so that the first conversion gain transistor CG1, the second conversion gain transistor CG2, and the reset transistor RST are all closed. This causes the floating diffusion node FD to be set to V_{DD} and the LOFIC to discharge.

To enter the low conversion gain mode, the reset control signal V_{RT_A} is set to low while the conversion gain control signals V_{CG1_A} and V_{CG2_A} remain high. This causes the floating diffusion node FD to float and to include the capacitances of the first and second conversion gain transistors CG1 and CG2 and the LOFIC. This condition may be maintained until the next read operation that includes the floating diffusion node FD, after which the reset operation may be repeated.

To enter the medium conversion gain mode, the reset control signal V_{RT_A} and the conversion gain control signal V_{CG2_A} are set low while the conversion gain control signal V_{CG1_A} remains high. This causes the floating diffusion node FD to include the capacitance of the source/drain region 411 (see FIG. 4) and other capacitances associated with first conversion gain transistors CG1, but not the capacitance of the LOFIC. The source/drain region 411 may be larger or have heavier doping than any of the source/drain regions that are always coupled to the floating diffusion node FD such as the drain region of the transfer gate TX (also called the floating diffusion region), the source region of the first conversion gain transistors CG1, and a source/drain region associated with the bridge circuit 107 (see FIG. 4). These other source/drain regions may be kept small and have the lightest doping that provides functionality in order to keep the capacitance of the floating diffusion node FD low in the high conversion gain mode. On the other hand, the capacitance of the source/drain region 411 may be made as large or larger than all these other source/drain regions in order to provide a substantial increase in the capacitance of the floating diffusion node FD on transition from the high conversion gain mode to the medium conversion gain mode. In some embodiments, adding the source/drain region 411 to the floating diffusion node FD at least doubles the capacitance of the floating diffusion node FD.

To enter the high conversion gain mode, the conversion gain control signals V_{CG1_A} and V_{CG2_A} are set low together with the reset control signal V_{RT_A}. This causes the floating diffusion node FD to float and to be isolated from the capacitance of the source/drain region 411 and the LOFIC. This condition may be maintained until the next read operation, after which the reset operation may again be repeated.

The low, medium, and high conversion gain modes may be used in connection with either the 1C mode, the 2C mode, or the 4C mode. In the 4C mode, the reset operations for the four photodetector pixel circuits 401A-401D may be carried out simultaneously. In the 1C mode, the reset operations for the four photodetector pixel circuits 401A-401D may be carried out asynchronously. In the 4C mode, the transfer gates TX may be opened simultaneously to initiate a read operation. Synchronous operation increases the read operation speed. In the 1C mode, the transfer gates TX may be opened asynchronously. Asynchronous operation allows the column wires 403A and 403B (see FIG. 4) to be shared between photodiodes PD in the quad pixel circuit 405.

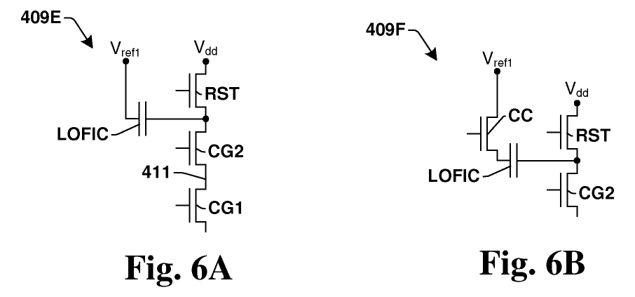

FIG. 6A-6B provide circuit diagrams 600A-600B for multiple conversion gain circuits 409E-409F according to various other embodiments. The multiple conversion gain circuit 409E is among the alternatives for the triple conversion gain circuits 409A-409D in the example of FIG. 4. In the multiple conversion gain circuit 409E of FIG. 6A, the capacitor control transistor CC (see FIG. 4) has been replaced by a direct connection to V_{dd}. In the triple conversion gain circuit 409F of FIG. 6B, the LOFIC is connected to ground rather than to V_{ref1}. In the triple conversion gain circuit 409F of FIG. 6B, the first conversion gain transistor CG1 has been eliminated so that the illustrated circuit is simplified to a dual conversion gain circuit that provides only a low conversion gain mode and a high conversion gain mode. In some embodiments, V_{ref1} is V_{DD}. In some embodiments, V_{ref1} is ground. In some embodiments, V_{ref1} is a negative voltage bias (polarity opposite V_{DD}). In some embodiments, V_{ref1} is an indeterminate floating voltage. Each of these options provides a slightly different behavior for the corresponding multiple conversion gain circuit and any one of these options may provide the best performance for a particular application. The capacitor control transistor CC, when provided, may be operated to further tune the behavior of these multiple conversion gain circuits.

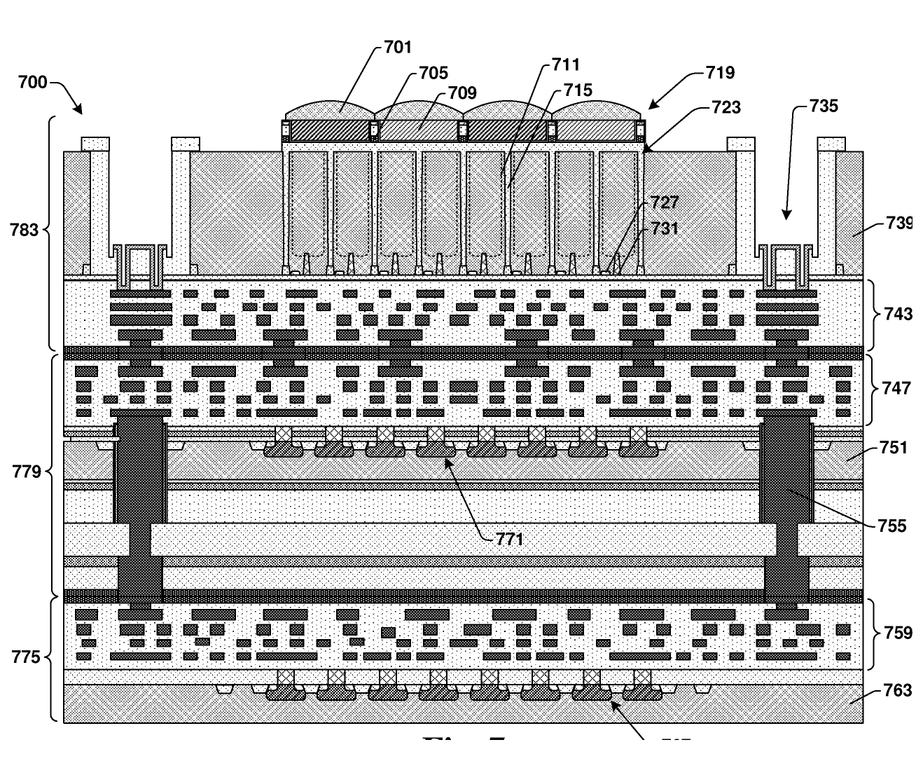

FIG. 7 illustrates a cross-sectional view of an image sensor 700 according to some embodiments. The image sensor 700 is an integrated circuit (IC) device and may be a 3D-IC including a first chip 783, a second chip 779, and a third chip 775 stacked, bonded, and interconnected together. The first chip 783 includes a first semiconductor substrate 739 and a first metal interconnect structure 743. The second chip 779 includes a second semiconductor substrate 751 and a second metal interconnect structure 747. The third chip 775 includes a third semiconductor substrate 763 and a third metal interconnect structure 759.

Photodiodes 711 in a first array 723 are disposed within the first semiconductor substrate 739. A deep trench isolation (DTI) structure 715 provides electrical isolation between the photodiodes 711 that are adjacent. Microlenses 701 and color filters 709 are in a second array 719 that is over the first array 723. A back side metal grid 705 provides optical isolation between color filters 709 that are adjacent. The second array 719 has one fourth a number density of the first array 723 so there are four of the photodiodes 711 for each of the color filters 709. The four photodiodes 711 under each color filter 709 form two-by-two subarrays and are in quad pixel circuits. The quad pixel circuits may correspond to the quad pixel circuit 105 of FIG. 1 or any of the other quad pixel circuits provided by the present disclosure.

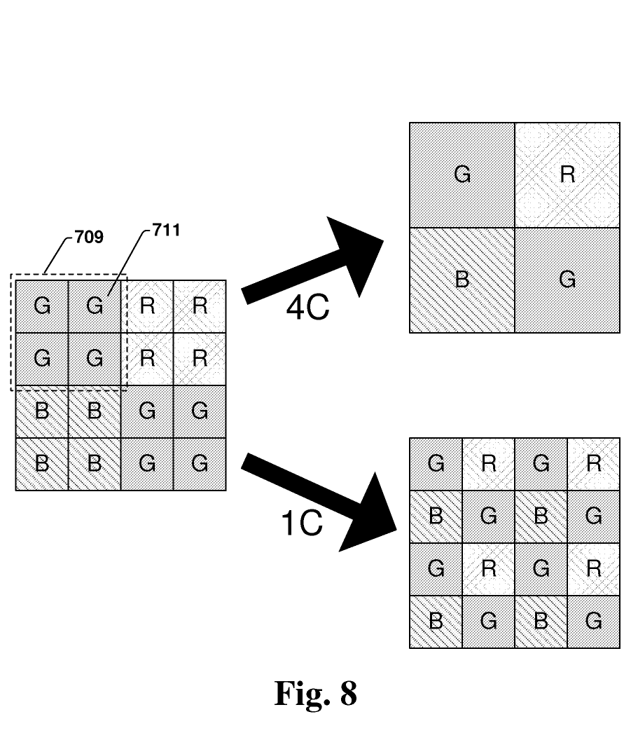

FIG. 8 illustrates the formation of images from a quad pixel structure like the one used in the image sensor 700 of FIG. 7 in 1C and 4C modes. As shown in FIG. 8, the color filters 709 may be green (G), red (R), and blue (B) and arranged in a Bayer pattern. In 4C mode, the image data from the photodiodes 711 is mapped in accordance with the color filter layout. In 1C mode, the image data from the photodiodes 711 may be mapped into the format a Bayer pattern image corresponding to the higher resolution. Interpolation may be used for pixel locations in the mapped image that are offset from actual pixels locations having the same color.

FIG. 9 provides a circuit diagram 900 illustrating how components of the photodetector pixel circuit 401A (see FIG. 4), components of the bridge circuit 107 (represented by the switch transistor 201A), and an application specific integrated circuit (ASIC) may be distributed in a 3D-IC including the first chip 783, the second chip 779, and the third chip 775 (see FIG. 7). As shown in FIG. 9, the photodiode PD and the transfer gate TX may be disposed on the first chip 783. Other components of the photodetector pixel circuit 401A (see FIG. 4) including the source follower SF, the row select transistor RSL, and the triple conversion gain circuit 409A may be disposed on the second chip 779, which leaves more area for the photodiode PD on the first chip 783. Components of the bridge circuit 107 (see FIG. 4) such as the switch transistor 201A of the bridge circuit 107A (see FIG. 2) may also be disposed on the second chip 779. The floating diffusion node FD includes some components on the first chip 783, such as the drain region of the transfer gate TX (which may be referred to as the floating diffusion region), some components on the second chip 779, such as the source region of the first conversion gain transistor CG1, and wiring between the first chip 783 and the second chip 779. The ASIC may be disposed on the third chip 775.

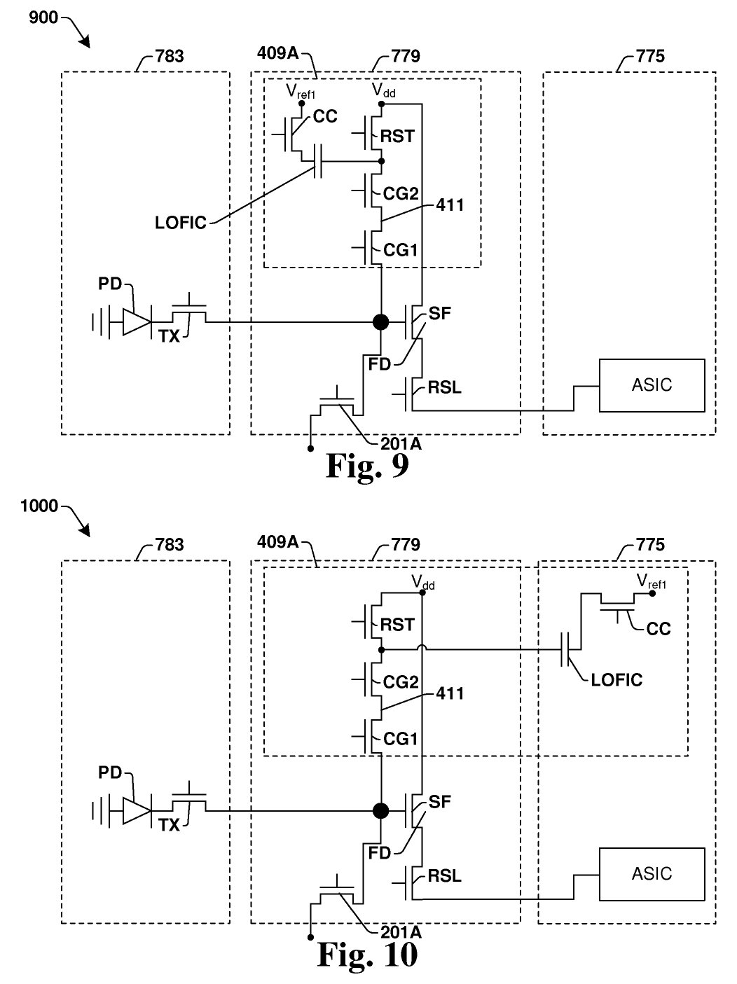

FIG. 10 provides a circuit diagram 1000 illustrating a distribution of components among the first chip 783, the second chip 779, and the third chip 775 in accordance with another embodiment. The distribution of components illustrated by the circuit diagram 1000 of FIG. 10 differs from the distribution of components illustrated by the circuit diagram 900 of FIG. 9 in that the LOFIC is on the third chip 775. This configuration facilitates providing one LOFIC for each photodiode PD. The capacitor control transistor CC, if included, may be kept on the same chip as the LOFIC to reduce routing.

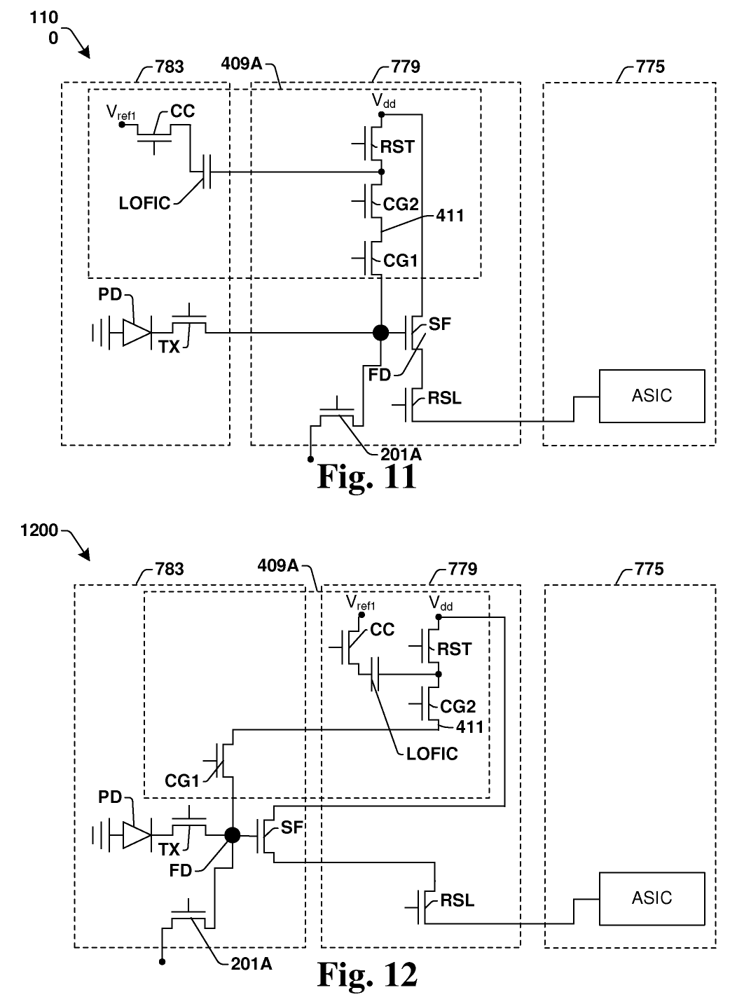

FIG. 11 provides a circuit diagram 1100 illustrating a distribution of components among the first chip 783, the second chip 779, and the third chip 775 in accordance with another embodiment. The distribution of components illustrated by the circuit diagram 1100 of FIG. 11 differs from the distribution of components illustrated by the circuit diagram 900 of FIG. 9 in that the LOFIC is on the first chip 783. This configuration also facilitates providing one LOFIC for each photodiode PD. The LOFICs are in the first metal interconnect structure 743 (see FIG. 7) and so do not reduce the area available for the photodiodes PD.

FIG. 12 provides a circuit diagram 1200 illustrating a distribution of components among the first chip 783, the second chip 779, and the third chip 775 in accordance with another embodiment. In the embodiment of FIG. 12, the first conversion gain transistor CG1 (or just a reset transistor in the absence of a multiple conversion gain circuit), the source follower SF, and the switch transistor 201A are on the first chip 783 while other components of the photodetector pixel circuit 401A (see FIG. 4) are on the second chip 779. In this embodiment, all the components that are part of the floating diffusion node FD in the high conversion gain mode are on the first chip 783. An advantage of this configuration is that the floating diffusion node FD does not have capacitance associated with wiring that extends between the first chip 783 and the second chip 779 when in the high conversion gain mode.

FIG. 13 provides a circuit diagram 1300 illustrating a distribution of components between the first chip 783 and the second chip 779 in accordance with an embodiment suitable for a two device layer 3DIC. In the embodiment of FIG. 13, all the components of the photodetector pixel circuit 401A (see FIG. 4) and of the bridge circuit 107 (represented by the switch transistor 201A) are on the first chip 783. The ASIC may be disposed on the second chip 779.

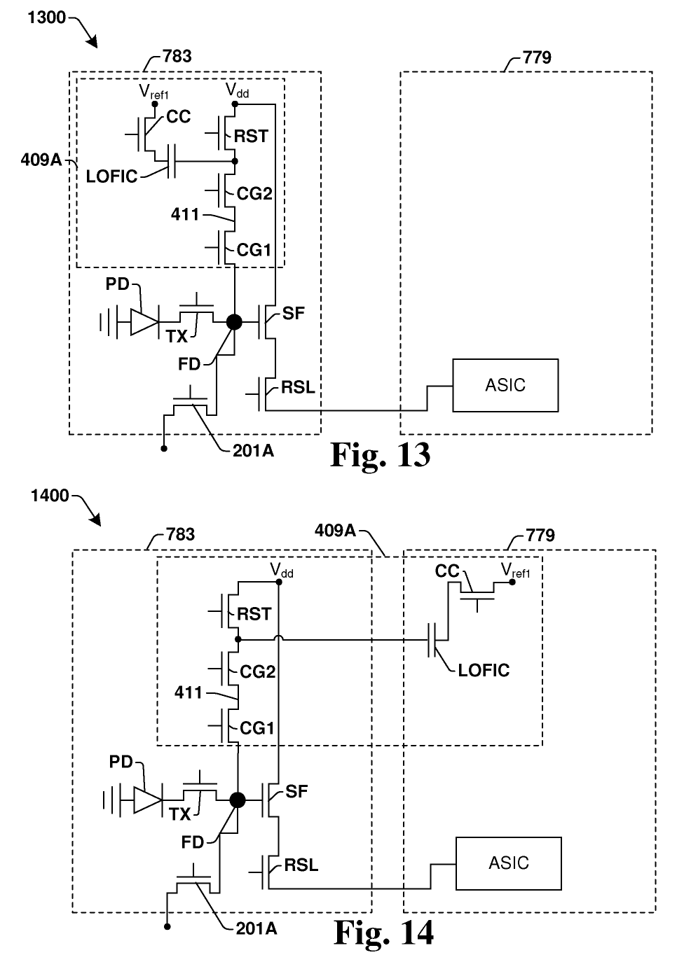

FIG. 14 provides a circuit diagram 1400 illustrating a distribution of components between the first chip 783 and the second chip 779 in accordance with another embodiment suitable for a two device layer 3DIC. The embodiment of FIG. 14 is like the embodiment of FIG. 13 except that the LOFIC is on the second chip 779 together with the ASIC.

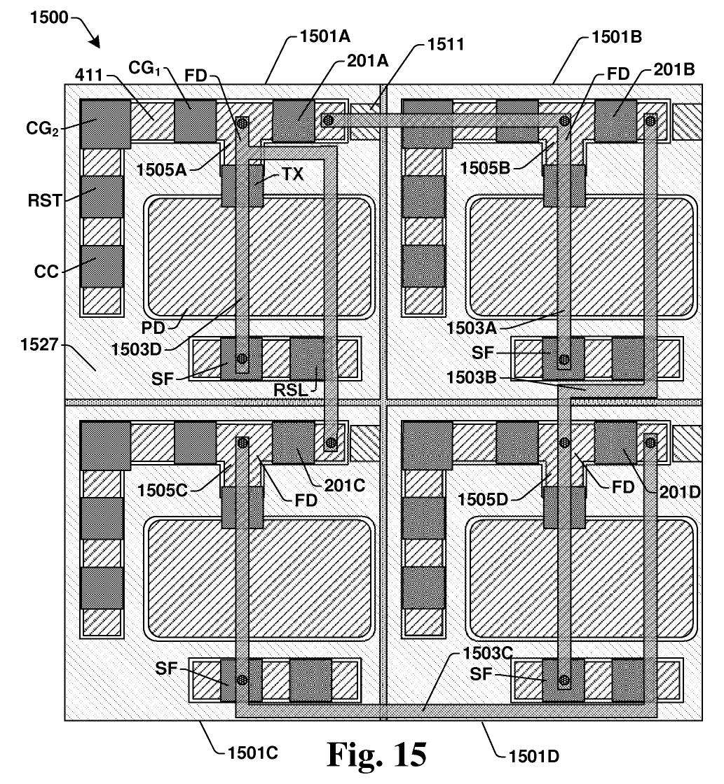

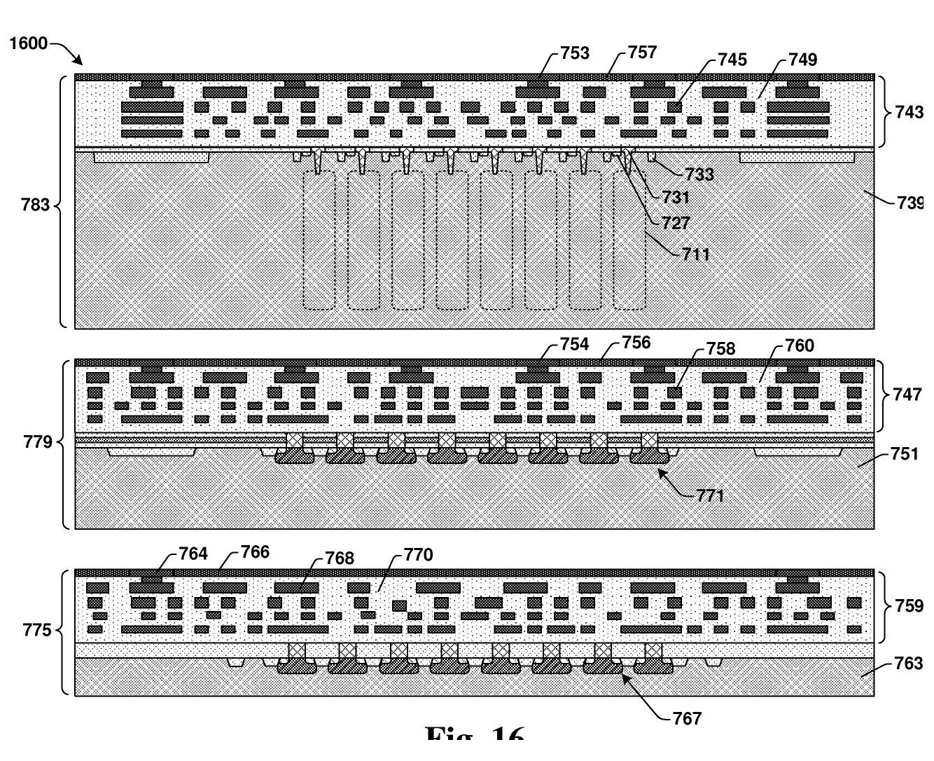

FIG. 15 provides a plan view 1500 showing a possible layout for the transistors of a quad pixel circuit on the first chip 783 consistent with the circuit diagrams 1300 of FIG. 13 and 1400 of FIG. 14. The plan view 1500 illustrates four pixel areas, which are pixel areas 1501A-1501D. The photodiodes PD and the source/drain regions have n-type doping. A p-doped area 1527 provides an isolation structure. A heavily p-doped area 1511 may be used for a contact that maintains the heavily p-doped area 1511 at a ground voltage or some other fixed bias voltage.

A wiring structure 1503A connects a source/drain region of the switch transistor 201A to the floating diffusion region 1505B in the pixel area 1501B. The wiring structure 1503A also connect the floating diffusion region 1505B to the gate electrode of the source follower SF in the pixel area 1501B.

A wiring structure 1503B connects a source/drain region of the switch transistor 201B to the floating diffusion region 1505D in the pixel area 1501D. The wiring structure 1503B also connect the floating diffusion region 1505D to the gate electrode of the source follower SF in the pixel area 1501D.

A wiring structure 1503C connects a source/drain region of the switch transistor 201D to the floating diffusion region 1505C in the pixel area 1501C. The wiring structure 1503C also connect the floating diffusion region 1505C to the gate electrode of the source follower SF in the pixel area 1501C.

A wiring structure 1503D connects a source/drain region of the switch transistor 201C to the floating diffusion region 1505A in the pixel area 1501A. The wiring structure 1503D also connect the floating diffusion region 1505A to the gate electrode of the source follower SF in the pixel area 1501A.

FIGS. 16-22 illustrate a series of cross-sectional views of components of an image sensor at various stages of manufacture according to a process of the present disclosure. Although FIGS. 16-22 are described in relation to a series of acts, it will be appreciated that the order of the acts may in some cases be altered and that this series of acts are applicable to structures other than the ones illustrated. In some embodiments, some of these acts may be omitted in whole or in part. Furthermore, although FIGS. 16-22 are described in relation to a series of acts, it will be appreciated that the structures shown in FIGS. 16-22 are not limited to a method of manufacture but rather may stand alone as structures separate from the method.

The method may begin with front-end-of-line (FEOL) and back-end-of-line (BEOL) processing for each of the first chip 783, the second chip 779, and the third chip 775. Although these are referred to as chips, at this stage of processing they may be wafers. FIG. 16 illustrates the first chip 783, the second chip 779, and the third chip 775 at the conclusion of FEOL and BEOL processing. Up to this point, these three device layers may be processed separately and in any order.

The first chip 783 includes the photodiodes 711 which are formed in the first semiconductor substrate 739. A semiconductor substrate may be a bulk semiconductor substrate or a semiconductor on insulator (SOI) substrate. At least an upper portion of a semiconductor substrate is a semiconductor. The semiconductor may be, for example, silicon (Si), a group III-V semiconductor or some other binary semiconductor, a tertiary semiconductor (e.g., AlGaAs), a higher order semiconductor, or the like. In some embodiments, the semiconductor is or comprises silicon (Si) or the like. The photodiodes 711 may be formed by ion implantation into the first semiconductor substrate 739 during FEOL processing. Additional structures formed during FEOL processing may include, for example, the transfer gates 731, the floating diffusion regions 727, and the isolation structures 733.

The first metal interconnect structure 743 including wires 745 surrounded by interlevel dielectric 749 is formed during BEOL processing. The wires 745 are arranged in a plurality of metallization layers. Vias (not shown) connect wires 745 between adjacent metallization. Wires and vias in a metal interconnect structure may be or comprise copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, the like, or any other suitable conductive materials. Wires and vias may also include diffusion barrier layers such as titanium (Ti), tantalum (Ta), titanium nitride (TiN), tantalum nitride (TaN), or the like. An interlevel dielectric may include one or more layers of silicon dioxide (SiO₂), a low-ĸ dielectric, or an extremely low-ĸ dielectric. A low-ĸ dielectric is one having a smaller dielectric constant than silicon dioxide (SiO₂). Examples of low-ĸ dielectrics include organosilicate glasses (OSG) such as carbon-doped silicon dioxide, fluorine-doped silicon dioxide (otherwise referred to as fluorinated silica glass (FSG), organic polymer low low-ĸ dielectrics, and porous silicate glass. A metal interconnect structure may also include etch stop layers. An etch stop layer may be aluminum oxide (AlOx), silicon nitride (SiN), silicon carbide (SiC), silicon carbonitride (SiCN), silicon oxycarbide (SiOC), silicon oxycarbonitiride (SiOCN), combinations thereof, or the like.

The uppermost layer of the of the first metal interconnect structure 743 is a bonding layer. The bonding layer includes contact pads 753 and dielectric 757. The contact pads 753 may be one of the metals mentioned as suitable for wires. In some embodiments, the contact pads 753 are a metal that is suitable for metal-to-metal bonding. In some embodiments, the dielectric 757 is silicon dioxide (SiO₂), silicon oxynitride (SiON), the like, or some other dielectric suitable for dielectric-to-dielectric bonding.

FEOL processing of the second chip 779 provides the transistors 771. BEOL processing provides the second metal interconnect structure 747 which includes wires 758 and interlevel dielectric 760. The uppermost layer of the second metal interconnect structure 747 is a bonding layer. The bonding layer may include the contact pads 754 and a bonding dielectric 756.

FEOL processing of the third chip 775 provides the transistors 767 and other components of an ASIC (not shown). BEOL processing provides the third metal interconnect structure 759 which includes wires 768 and interlevel dielectric 770. The uppermost layer of the third metal interconnect structure 759 is a bonding layer. The bonding layer may include the contact pads 764 and a bonding dielectric 766.

LOFICs (not shown) may be formed during BEOL processing and may be in either the first metal interconnect structure 743, the second metal interconnect structure 747, or the third metal interconnect structure 759. In some embodiments, the LOFICs are metal-insulator-metal capacitors. In some embodiments, the LOFICs are trench-type capacitors. In some embodiments, the LOFICs are metal-oxide-metal capacitors. In some embodiments, the LOFICs comprise interdigitated metal plates. In some embodiments, the LOFICs are disposed in the uppermost metallization layer of a metal interconnect structure.

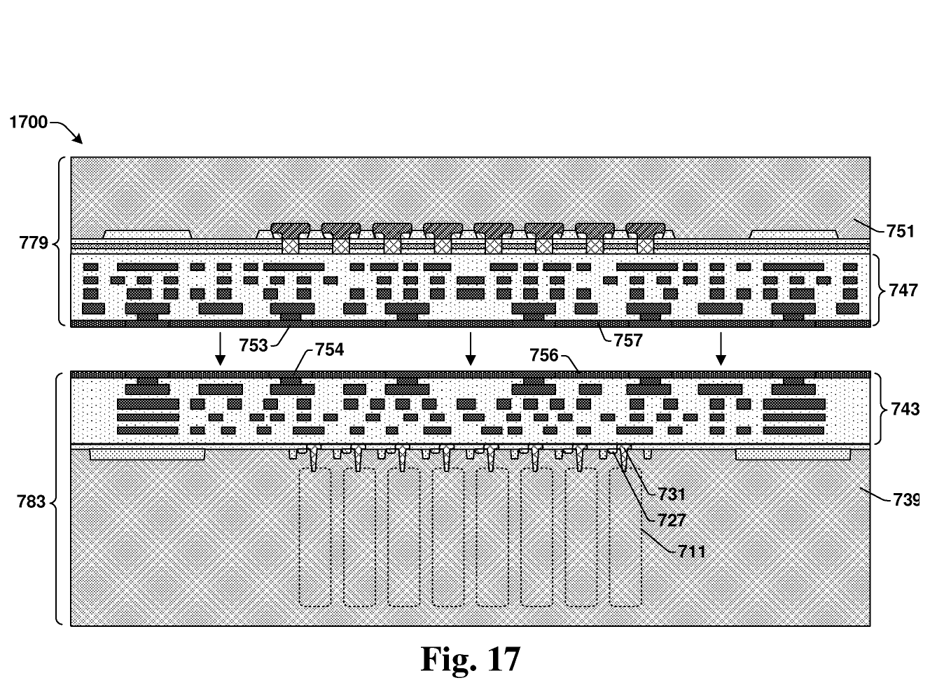

As shown by the cross-sectional view 1700 of FIG. 17, the process may continue with bonding the second chip 779 to the first chip 783. The bonding may be dielectric-to-dielectric bonding between the bonding dielectric 756 and the bonding dielectric 757, metal-to-metal bonding between the contact pads 754 and the contact pads 753, or both dielectric-to-dielectric and metal-to-metal bonding. In either case, electrical connections are formed between the contact pads 754 and the contact pads 753.

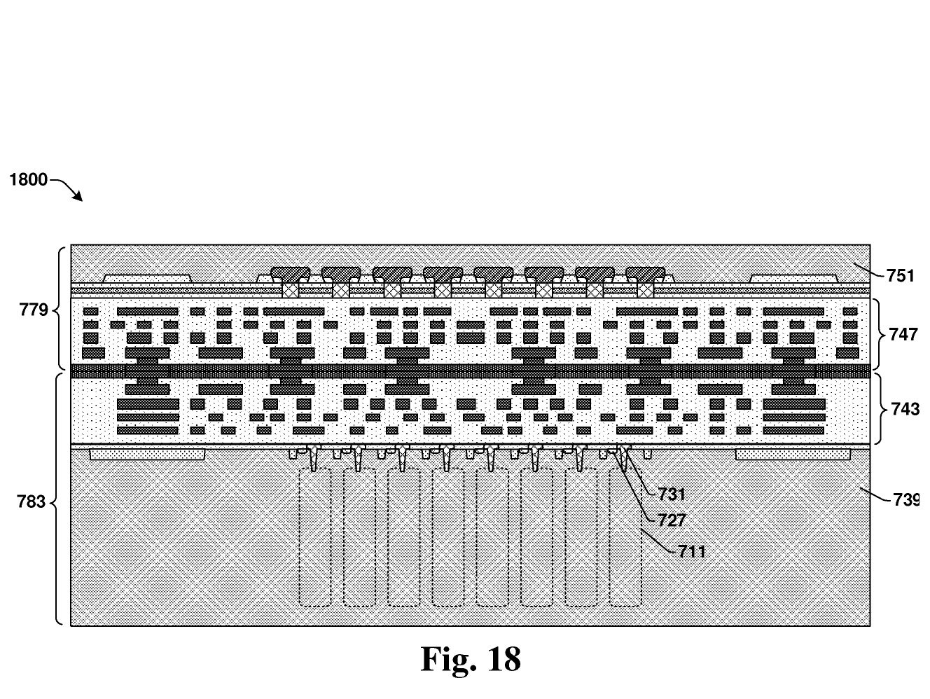

As shown by the cross-sectional view 1800 of FIG. 18, the second semiconductor substrate 751 may be thinned from the back side. The second semiconductor substrate 751 may be thinned by etching, mechanical grinding, CMP, the like, or some other suitable process or processes. In some embodiments, thinning reduces the second semiconductor substrate 751 to a thickness in the range from about 1 µm to about 10 µm. In some embodiments, thinning reduces the second semiconductor substrate 751 to a thickness of about 5 µm or less. In some embodiments, thinning reduces the second semiconductor substrate 751 to a thickness of about 3 µm or less. If the second semiconductor substrate 751 is left too thick, it may be impractical to form TSVs. If the second semiconductor substrate 751 is left too thin, it may be structurally unstable.

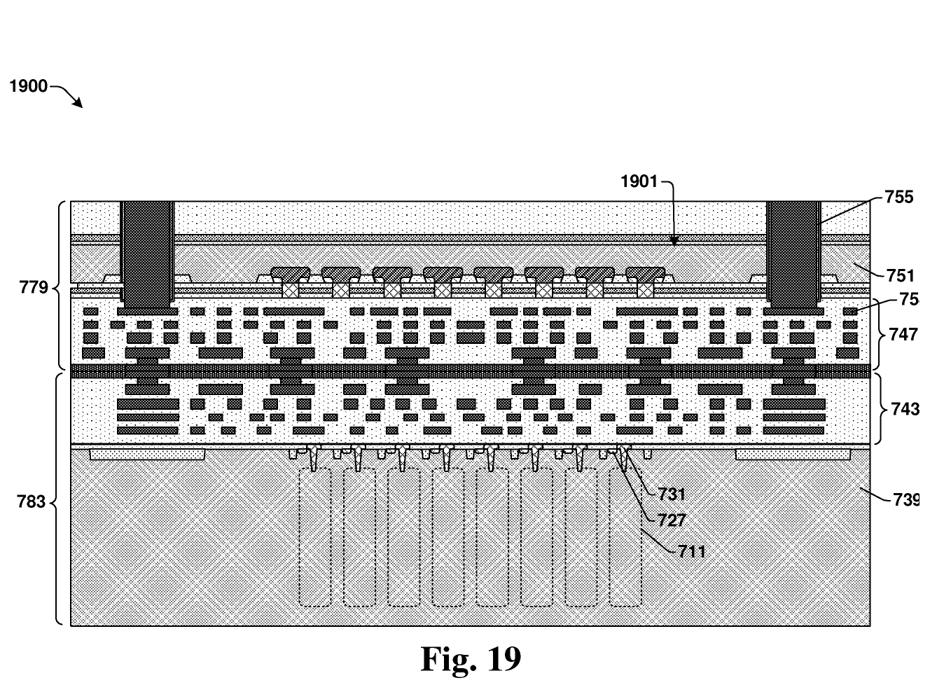

As shown by the cross-sectional view 1900 of FIG. 19, TSVs 755 may be formed through the second semiconductor substrate 751. The process may include forming an isolation structure on the back side 1901, etching holes that land on wires 758 in the second metal interconnect structure 747, lining the holes with dielectric, conducting a breakthrough etch to expose the wires, filing the holes with conductive material, and planarizing. The conductive material may be doped polysilicon, a metal, or some other suitable conductor. If the conductive material is a metal, the metal may be or comprise, for example, copper (Cu), aluminum (Al), silver (Ag), tin (Sn), Indium (In), nickel (Ni), or the like.

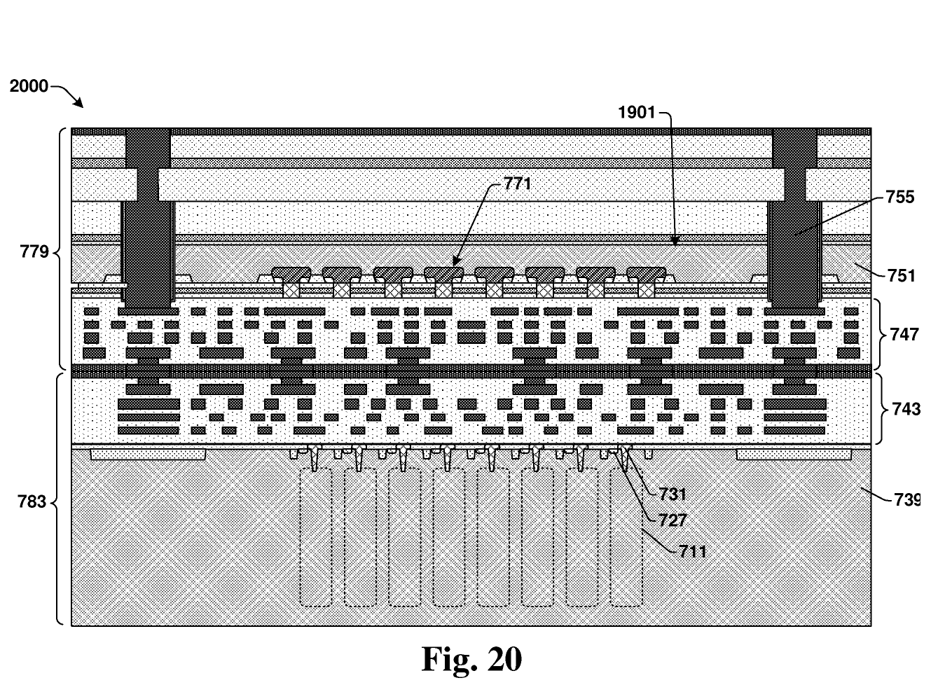

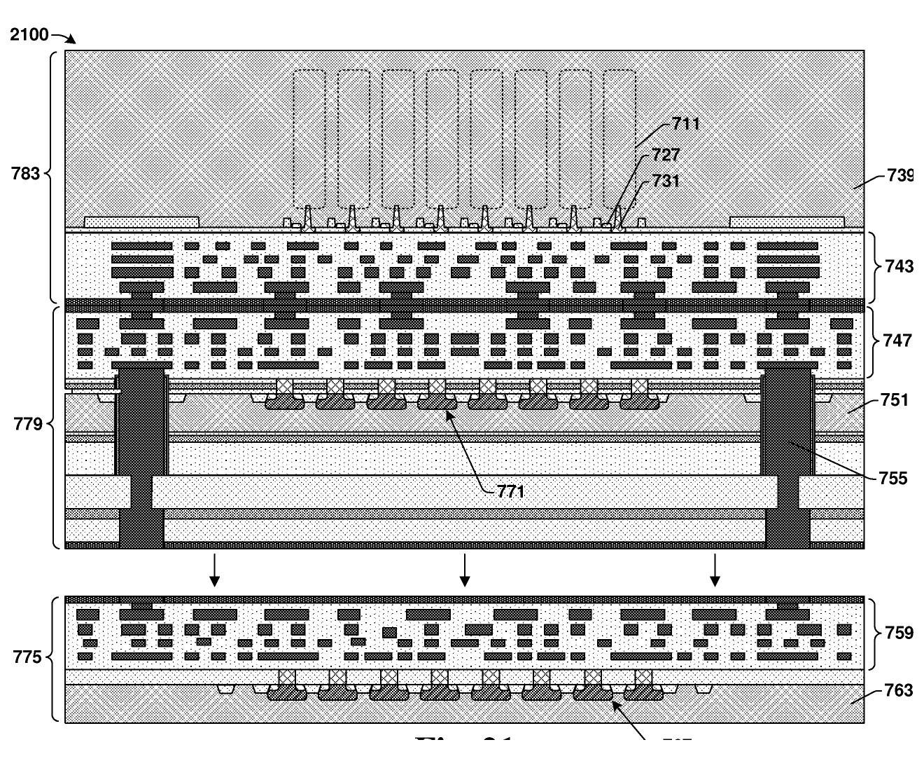

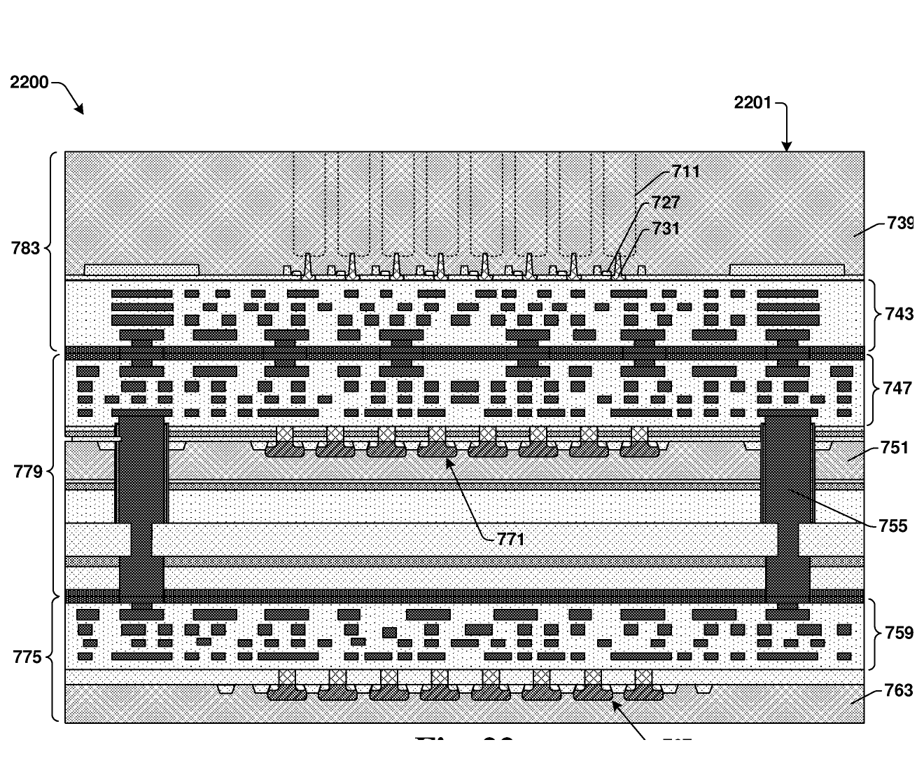

As shown by the cross-sectional view 2000 of FIG. 20 a bonding structure maybe formed over the back side 1901. As shown by the cross-sectional view 2100 of FIG. 21, the second chip 779, with the first chip 783 attached, may be bonded to the third chip 775. The bonding may be dielectric-to-dielectric bonding, metal-to-metal bonding, or both dielectric-to-dielectric and metal-to-metal bonding.

As shown by the cross-sectional view 2200 of FIG. 22, the first semiconductor substrate 739 may then be thinned from the back side 2201. The first semiconductor substrate 739 may be thinned by etching, mechanical grinding, CMP, the like, or some other suitable process or processes. In some embodiments, thinning reduces the second semiconductor substrate 751 to a thickness in the range from about 1 µm to about 10 µm. In some embodiments, thinning reduces the first semiconductor substrate 739 to a thickness of about 5 µm or less. In some embodiments, thinning reduces the second semiconductor substrate 751 to a thickness of about 3 µm or less. If the first semiconductor substrate 739 is left too thick, light may not effectively penetrate to the photodiodes 711. If the first semiconductor substrate 739 is left too thin, light may not be efficiently captured by the photodiodes 711. Additional processing may provide the DTI structure 715, the back side metal grid 705, the color filters 709, the microlenses 701, the contact pads 735, and so produce a structure as shown in FIG. 7.

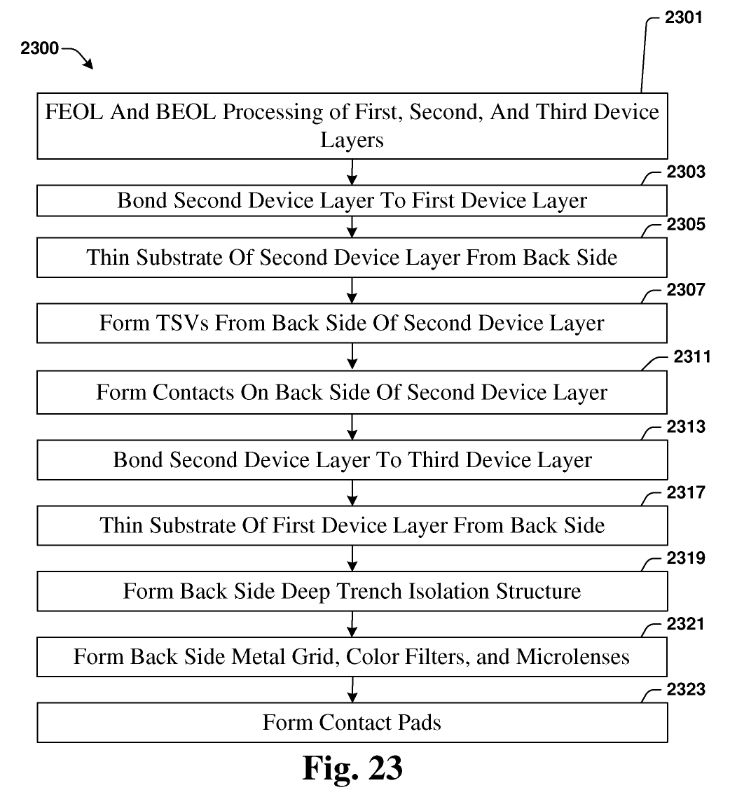

FIG. 23 provides a flow diagram for a process 2300 of forming an image sensor of the present disclosure. While the process 2300 is illustrated and described below as a series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The process 2300 begins act 2301, which is FEOL and BEOL processing of first, second, and third device layers. The cross-sectional view 1600 of FIG. 16 provide examples of these device layers after this initial processing. Each of the device layers may be a separate wafer at this stage of processing. The wafers may be subsequently diced to form chips. FEOL processing forms wells, transistors, diodes, isolation structures, and the like in the substrates. BEOL processing forms metal interconnect structures, capacitors, and bonding structures. The first device layer may contain an array of photodiodes or other photodetector structures, transfer gates, and the like. The second device layer may include some photodetector pixel circuit components. Either the first device layer or the second device layer may contain row drivers and column decoders for the photodiode array. The third device layer may include an ASIC.

Act 2303 is aligning the first and second device layers and bonding them together through their respective bonding layers. The cross-sectional view 1700 of FIG. 17 provides an example.

Act 2305 is thinning the semiconductor substrate of the second device layer from the back side. The cross-sectional view 1800 of FIG. 18 provides an example.

Act 2307 is forming TSVs through the semiconductor substrate of the second device layer from the back side. The cross-sectional view 1900 of FIG. 19 provides an example.

Act 2311 is forming contacts and a bonding structure on the back side of the second device layer. The cross-sectional view 2000 of FIG. 20 provides an example.

Act 2313 is aligning the second and third device layers and bonding them together so that the TSVs are coupled to the third device layer. The cross-sectional view 2100 of FIG. 21 provides an example.

Act 2317 is thinning the semiconductor substrate of the first device layer from the back side. The cross-sectional view 2200 of FIG. 22 provides an example.

Act 2319 is forming a DTI structure from the back side of the semiconductor substrate of the first device layer. Act 2321 is additional processing that forms a back side metal grid, color filters, and microlenses on the back side of the semiconductor substrate of the first device layer. Act 2323 is forming contact pads on the back side of the semiconductor substrate of the first device layer. FIG. 7 provides an example of the resulting structure.

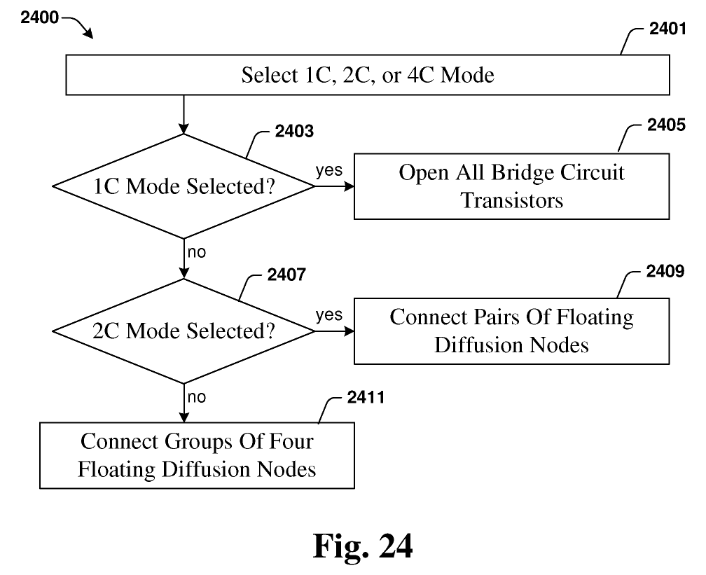

FIG. 24 is a flow chart for a method 2400 for operating an image sensor having a quad pixel structure according to the present disclosure. The method begins with act 2401, selecting among 1C, 2C, and 4C modes. Act 2403 is determining if 1C mode has been selected. If 1C mode has been selected, then act 2405 operates the bridge circuits to isolate the floating diffusion nodes in each quad pixel array. If 1C mode has not been selected, then act 2407 determines whether 2C mode has been selected. If 2C mode has been selected, then act 2409 operates the bridge circuits so that pairs of floating diffusion nodes in each quad pixel array are coupled. If 2C mode has been selected, then act 2411 operates the bridge circuits so that all four floating diffusion nodes in each quad pixel array are electrically coupled.

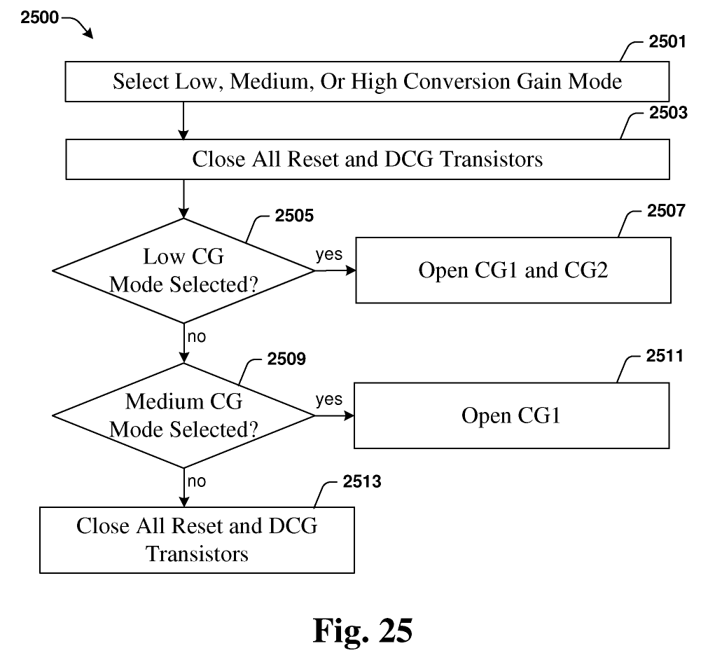

FIG. 25 is a flow chart for a method 2500 for operating an image sensor having triple conversion gain circuits and a quad pixel structure according to the present disclosure. The method 2500 is compatible with the method 2400 of FIG. 24. The method 2500 begins with act 2501, selecting low, medium, or high conversion gain mode. Act 2503 is executing a rest operation, which may include closing all the reset and conversion gain transistors in a triple conversion gain circuit. Act 2505 is determining if low conversion gain mode has been selected. If low conversion gain mode has been selected, then act 2507 opens the reset transistors while leaving the conversion gain transistors closed. If low conversion gain mode has not been selected, then act 2509 determines whether medium conversion gain mode been selected. If medium conversion gain mode has been selected, then act 2511 opens the reset transistors and the second conversion gain transistor but leaves the first conversion gain transistor closed. If 2C mode has not been selected, then act 2513 opens all the reset transistors and all the conversion gain transistors.

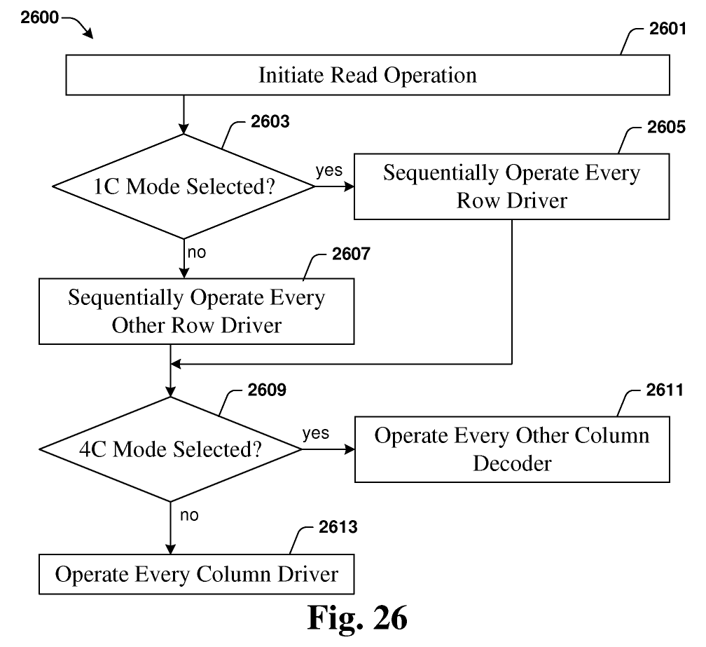

FIG. 26 is a flow chart for a method 2600 for executing a read operation for an image sensor having a quad pixel structure according to an embodiment of the present disclosure. Act 2601 is determining to initiate the read operation. The determination may be made based on a clock. Act 2603 is determining whether 1C mode has been selected. If 1C mode has been selected, then act 2605 sequentially operates each row driver for the photodetector array. If 1C mode has not been selected, then act 2607 sequentially operates every other row driver for the photodetector array. In either case, the method continues with act 2609. Act 2609 determined whether 4C mode has been selected. If 4C mode has not been selected, then act 2613 operates every column decoder for the photodetector array. If 4C mode has been selected, the act 2611 operates only every other column decoder for the photodetector array.

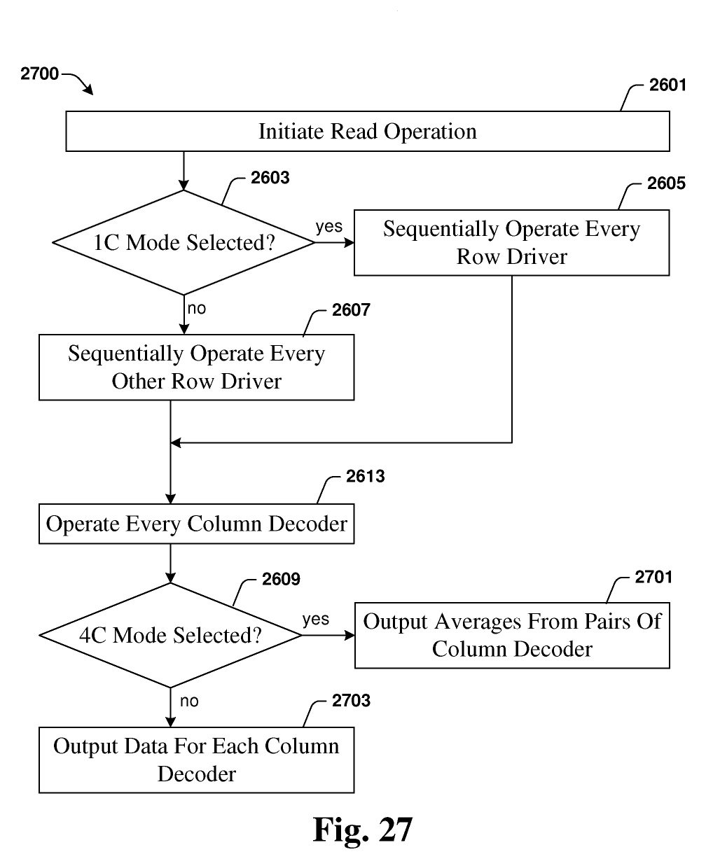

FIG. 27 is a flow chart for a method 2700 for executing a read operation for an image sensor having a quad pixel structure according to another embodiment of the present disclosure. The method 2700 contains many of the same steps as the method 2600 of FIG. 26. But in the method 2700, act 2613, which is operating every column decoder, is executed in every case, and act 2609, determining whether 4C mode has been selected, may come after act 2613. In the method 2700, if 4C mode has not been selected, then act 2703 outputs the data from each column decoder in a conventional manner. If 4C mode has been selected, then act 2701 outputs an average value for the values produced by each pair of column decoders.

Some aspects of the present disclosure relate to an image sensor that includes photodiodes in a first array within a first semiconductor substrate, a quad pixel circuit, and a bridge circuit. The quad pixel circuit comprises four of the photodiodes in a two-by-two subarray, four transfer gates, four floating diffusion regions, and four source followers. The bridge circuit selectively couples the four floating diffusion regions. In some embodiments, the quad pixel circuit further comprises four multiple conversion gain circuits. In some embodiments the four multiple conversion gain circuits comprise four LOFICs respectively. In some embodiments, the four multiple conversion gain circuits each comprise two transistors in series connected between respective LOFICs and respective floating diffusion regions. In some embodiments, the image sensor further comprises an integrated circuit that generates control signals that selectively operate the two transistors in series to independently determine low, medium, and high conversion gain modes.

In some embodiments, the image sensor further comprises an integrated circuit that generates control signals that operate the bridge circuit to connect groups that selectively include either one, two, or four of the four floating diffusion regions. In some embodiments, the image sensor further comprises two column decoders, two wiring structures, and an integrated circuit. Each of the wiring structures connects two of the four source followers to one of the two column decoders. The integrated circuit averages an output of the two column decoders when the bridge circuit is coupling the four floating diffusion regions.

In some embodiments, the image sensor further comprises two column decoders, two wiring structures, and an integrated circuit. Each of the wiring structures connects two of the four source followers to one of the two column decoders. The integrated circuit deactivates one of the two column decoders when the bridge circuit is coupling two of the four floating diffusion regions.

In some embodiments, the four source followers and the bridge circuit are on the first semiconductor substrate. In some embodiments, the four source followers and the bridge circuit are on a second semiconductor substrate, and the second semiconductor substrate is attached to the first semiconductor substrate. In some embodiments, the image sensor further comprises a row driver and a column decoder on the second semiconductor substrate. In some embodiments, the image sensor further comprises a through substrate via in the second semiconductor substrate and a third semiconductor substrate, wherein the third semiconductor substrate comprises an integrated circuit. The through substrate via connects the integrated circuit to the column decoder. In some embodiments, the image sensor further comprises color filters in a second array, wherein the second array has a one fourth a number density of the first array so that there are four of the photodiodes for each of the color filters.

Some aspects of the present disclosure relate to an image sensor that includes a semiconductor substrate, first second, third and fourth photodetectors and first second and third switch transistors. The first through fourth photodetectors include first through fourth photodiodes, first through fourth transfer gates, and first through fourth floating diffusion nodes respectively. The first transistor has a pair of source/drain regions electrically coupled to the first floating diffusion node and the second floating diffusion node respectively. The second transistor has a pair of source/drain regions electrically coupled to the third floating diffusion node and the fourth floating diffusion node respectively. The third transistor having a pair of source/drain regions electrically coupled to the first floating diffusion node and the third floating diffusion node respectively. In some embodiments, the image sensor further comprises a fourth transistor having a pair of source/drain regions electrically coupled to the second floating diffusion node and the fourth floating diffusion node respectively. In some embodiments, the image sensor further comprises first through fourth source followers having first through fourth gate electrodes, wherein the first through fourth floating diffusion nodes are coupled to the first through fourth gate electrodes respectively. The image sensor further comprises a column decoder. A wiring structure connects source regions of the first through fourth source followers to the column decoder.

Some aspects of the present disclosure relate to an image sensor that includes a first chip comprising a first semiconductor substrate, four photodetector pixel circuits each comprising a photodiode, a transfer gate, a floating diffusion node, a source follower, a dual conversion gain transistor, and a lateral overflow integration capacitor (LOFIC). The photodiodes are in the first semiconductor substrate. The photodiodes of the four photodetector pixel circuits are under a color filter. The image sensor further includes a bridge circuit that selectively couples the four floating diffusion nodes. In some embodiments, the image sensor further comprises a second chip attached to the first chip. The second chip comprises a second semiconductor substrate. The LOFICs are in the second chip, and the source followers are in the first chip.

In some embodiments, the image sensor further comprises a second chip including a second semiconductor substrate and a third chip comprising a third semiconductor substrate. The second chip is attached to the first chip and the third chip is attached to the second chip. The source followers are in the second chip. In some embodiments, the LOFICs are in the third chip. In some embodiments, the LOFICs are in the first chip.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
photodiodes in a first array within a first semiconductor substrate;
a quad pixel circuit, wherein the quad pixel circuit comprises four of the photodiodes in a two-by-two subarray, four transfer gates, four floating diffusion regions, and four source followers; and
a bridge circuit that selectively couples the four floating diffusion regions.

2. The image sensor of claim 1, wherein the quad pixel circuit further comprises four multiple conversion gain circuits.

3. The image sensor of claim 2, wherein the four multiple conversion gain circuits comprise four lateral overflow integration capacitors respectively.

4. The image sensor of claim 3, wherein the four multiple conversion gain circuits each comprise two transistors in series connected between respective lateral overflow integration capacitors and respective floating diffusion regions.

5. The image sensor of claim 3, further comprising an integrated circuit, wherein the integrated circuit generates first control signals that operate the bridge circuit to connect groups that selectively include either one, two, or four of the four floating diffusion regions and second control signals that selectively operate the four multiple conversion gain circuits to independently determine conversion gain modes.

6. The image sensor of claim 1, further comprising an integrated circuit, wherein the integrated circuit generates control signals that operate the bridge circuit to connect groups that selectively include either one, two, or four of the four floating diffusion regions.

7. The image sensor of claim 1, further comprising:
two column decoders;
two wiring structures, wherein each of the wiring structures connects two of the four source followers to one of the two column decoders; and
an integrated circuit that averages an output of the two column decoders when the bridge circuit is coupling the four floating diffusion regions.

8. The image sensor of claim 1, further comprising:
two column decoders;
two wiring structures, wherein each of the wiring structures connects two of the four source followers to one of the two column decoders; and
an integrated circuit that deactivates one of the two column decoders when the bridge circuit is coupling the four floating diffusion regions.

9. The image sensor of claim 1, wherein the four source followers and the bridge circuit are on the first semiconductor substrate.

10. The image sensor of claim 1, wherein the four source followers and the bridge circuit are on a second semiconductor substrate, and the second semiconductor substrate is attached to the first semiconductor substrate.

11. The image sensor of claim 10, further comprising a row driver and a column decoder on the second semiconductor substrate.

12. The image sensor of claim 1, wherein the quad pixel circuit further comprises four dual conversion gain circuits.

13. The image sensor of claim 1, further comprising color filters in a second array, wherein the second array has a one fourth a number density of the first array so that there are four of the photodiodes for each of the color filters.

14. An image sensor, comprising:
a semiconductor substrate;
a first photodetector comprising a first photodiode in the semiconductor substrate, a first transfer gate, and a first floating diffusion node;
a second photodetector comprising a second photodiode in the semiconductor substrate, a second transfer gate, and a second floating diffusion node;
a third photodetector comprising a third photodiode in the semiconductor substrate, a third transfer gate, and a third floating diffusion node;
a fourth photodetector comprising a fourth photodiode in the semiconductor substrate, a fourth transfer gate, and a fourth floating diffusion node;
a first transistor having a pair of source/drain regions electrically coupled to the first floating diffusion node and the second floating diffusion node respectively;
a second transistor having a pair of source/drain regions electrically coupled to the third floating diffusion node and the fourth floating diffusion node respectively; and
a third transistor having a pair of source/drain regions electrically coupled to the first floating diffusion node and the third floating diffusion node respectively.

15. The image sensor of claim 14, further comprising a fourth transistor having a pair of source/drain regions electrically coupled to the second floating diffusion node and the fourth floating diffusion node respectively.

16. The image sensor of claim 14, further comprising:
a first source follower having a first gate electrode, wherein the first floating diffusion node is coupled to the first gate electrode;
a second source follower having a second gate electrode, wherein the second floating diffusion node is coupled to the second gate electrode;
a third source follower having a third gate electrode, wherein the third floating diffusion node is coupled to the third gate electrode;
a fourth source follower having a fourth gate electrode, wherein the fourth floating diffusion node is coupled to the fourth gate electrode; and
a column decoder, wherein a wiring structure connects source regions of the first source follower, the second source follower, the third source follower, and the fourth source follower to the column decoder.

17. An image sensor, comprising:
a first chip comprising a first semiconductor substrate;
four photodetector pixel circuits each comprising a photodiode, a transfer gate, a floating diffusion node, a source follower, a multiple conversion gain transistor, and a lateral overflow integration capacitor (LOFIC), wherein the photodiodes are in the first semiconductor substrate;
a color filter, wherein the photodiodes of the four photodetector pixel circuits are under the color filter; and
a bridge circuit that selectively couples the four floating diffusion nodes.

18. The image sensor of claim 17, further comprising a second chip attached to the first chip, wherein the second chip comprises a second semiconductor substrate, the LOFICs are in the second chip, and the source followers are in the first chip.

19. The image sensor of claim 17, further comprising:
a second chip comprising a second semiconductor substrate, wherein the second chip is attached to the first chip; and
a third chip comprising a third semiconductor substrate; wherein the third chip is attached to the second chip, wherein the LOFICs are in the third chip, and the source followers are in the second chip.

20. The image sensor of claim 17, further comprising:
a second chip comprising a second semiconductor substrate, wherein the second chip is attached to the first chip; and
a third chip comprising a third semiconductor substrate; wherein the third chip is attached to the second chip, wherein the LOFICs are in the first chip, and the source followers are in the second chip.
